(19) United States
(12) Patent Application Publication
(10) Pub. No.: US 2007/0020771 A1
(43) Pub. Date: Jan. 25, 2007

(54) Nanoparticles and method of making thereof

(75) Inventors: Partha Dutta, Clifton Park, NY (US); Eric Burnett, Loudonville, NY (US)

Correspondence Address: FOLEY AND LARDNER LLP;SUITE 500, 3000 K STREET NW, WASHINGTON, DC, 20007, US

(73) Assignee: Applied NanoWorks, Inc.

(21) Appl. No.: 11/474,494

(22) Filed: Jun. 26, 2006

Related U.S. Application Data
(60) Provisional application No. 60/693,467, filed on Jun. 24, 2005.

(51) Int. Cl. H01L 21/00

(52) U.S. Cl. 438/1; 977/900

(57) ABSTRACT

A method of making nanoparticles includes contacting a powder having particles of a first size and an etching material, and heating the powder and the etching material to reduce particles of the first size to nanoparticles having a second size smaller than the first size.

### CROSS-REFERENCE TO RELATED PATENT APPLICATIONS

This application claims benefit of priority of U.S. Provisional Patent Application No. 60/693,467, filed Jun. 24, 2005, which is incorporated herein by reference in its entirety.

### FIELD OF THE INVENTION

The present invention is directed generally to compositions of matter and more particularly to nanoparticles and methods of making thereof.

### BACKGROUND OF THE INVENTION

In principle, nanoparticles of any material can be generated by thoroughly grinding a bulk solid of the given material, by a grinding process such as ball milling, as discussed, for example, in “Large-scale synthesis of ultrafine Si nanoparticles by ball milling” C. Lam, Y. F. Zhang, Y. H. Tang, C. S. Lee, I. Bello, S. T. Lee, Journal of Crystal Growth 220 (2000) 466-470. However as simple as it may appear, grinding does not lead to uniform particle sizes due to aggregation of the particles after they have been crushed and powdered to sub-micron chunks. To get nanoparticles below 100 nm, it may take up to several days of grinding, making the grinding process, such as a ball milling process, unsuitable for large scale production. When nanoparticles are produced by ball milling for a prolonged period of time, such as for several days, the nanoparticles are frequently contaminated and undesirable impurities of foreign materials have been detected in such nanoparticle samples. Thus, many commercial nanoparticle synthesis methods use high temperature processes, including formation of nanoparticles by reaction from chemicals or physical disintegration of big particles by pyrolysis. However, these methods are often complex, expensive, difficult to control due to the high process temperature and often use environmentally harmful and dangerous chemicals.

A relatively new correlative method for easier manipulation and spatial organization of the nanoparticles has been proposed in which the nanoparticles are encapsulated in a shell. The shells which encapsulate the nanoparticles are composed of various organic materials such as Polyvinyl Alcohol (PVA), PMMA, and PPV. Furthermore, semiconductor shells have also been suggested.

For example, U.S. Pat. Nos. 6,225,198 and 5,505,928, incorporated herein by reference, disclose a method of forming nanoparticles using an organic surfactant. The process described in the 6,225,198 patent includes providing organic compounds, which are precursors of Group II and Group VI elements, in an organic solvent. A hot organic surfactant mixture is added to the precursor solution. The addition of the hot organic surfactant mixture causes precipitation of the II-VI semiconductor nanoparticles. The surfactants coat the nanoparticles to control the size of the nanoparticles. However, this method is disadvantageous because it involves the use of a high temperature (above 200° C.) process and toxic reactants and surfactants. The resulting nanoparticles are coated with a layer of an organic surfactant and some surfactant is incorporated into the semiconductor nanoparticles. The organic surfactant negatively affects the optical and electrical properties of the nanoparticles.

In another prior art method, II-VI semiconductor nanoparticles were encapsulated in a shell comprising a different II-VI semiconductor material, as described in U.S. Pat. No. 6,207,229, incorporated herein by reference. However, the shell also interferes with the optical and electrical properties of the nanoparticles, decreasing quantum efficiency of the radiation and the production yield of the nanoparticles.

Furthermore, it has been difficult to form nanoparticles of a uniform size. Some researchers claimed to have formed nanoparticles in a solution having a uniform size based on transmission electron microscopy (TEM) measurements and based on approximating nanoparticle size from the position of the exciton peak in the absorption spectra of the nanoparticles. However, the present inventor has determined that both of these methods do not lead to an accurate determination of nanoparticle size in the solution.

TEM allows actual observation of a few nanoparticles precipitated on a substrate from a solution. However, since very few nanoparticles are observed during each test, the nanoparticle size varies greatly between observations of different nanoparticles from the same solution. Therefore, even if a single TEM measurement shows a few nanoparticles of a uniform size, this does not correlate to an entire solution of nanoparticles of a uniform size.

Using the absorption spectra exciton peak position to approximate nanoparticle size is problematic for a different reason. The exciton peak position does not show whether the individual nanoparticles in a solution are agglomerated into a large cluster. Thus, the size of the individual nanoparticles that is estimated from the location of the exciton peak in the absorption spectra does not take into account that the individual nanoparticles have agglomerated into clusters.

### SUMMARY

One embodiment of the invention provides a method of making nanoparticles, comprising contacting a powder having particles of a first size and an etching material, and heating the powder and the etching material to reduce particles of the first size to nanoparticles having a second size smaller than the first size.

Another embodiment of the invention provides a method of making nanoparticles, comprising etching a metal oxide powder with an etching material to generate metal or semiconductor oxide nanoparticles and a by-product, and oxidizing the by-product to generate additional metal or semiconductor oxide nanoparticles.

### BRIEF DESCRIPTION OF THE DRAWINGS

FIGS. 1, 2 and 3 are schematic illustrations of steps in methods of making nanoparticles according to embodiments of the invention.

FIG. 4 and 5 are plots of particle size distributions of the specific examples of an embodiment of the present invention.

### DETAILED DESCRIPTION OF THE EMBODIMENTS

The present inventors have realized that nanoparticles may be formed by a simple process which includes etching a powder at an elevated temperature to achieve a desired nanoparticle size. If desired, some of the by-products of the etching may be recycled to form additional nanoparticles.

The term nanoparticles includes particles having an average size between about 2 and about 100 nm, preferably particles having an average size between about 2 and about 50 nm. Most preferably, the nanoparticles have an average size between about 2 and about 10 nm. Preferably, the first standard deviation of the size distribution is 60% or less, preferably 40% or less, most preferably 10 to 25% of the average particle size.

A method of making nanoparticles includes providing a powder having particles of a first average size, such as nanoparticles and/or microparticles. The powder having particles of a first size is etched at an elevated temperature to generate nanoparticles having a desired second size smaller than the first size.

The powder may comprise a ceramic material powder. For example, the ceramic material may comprise silica, alumina, titania, zirconia, yttria stabilized zirconia, yttria, ceria, spinel (for example, MgO*Al₂O₃) and tantalum pentoxide, as well as other suitable ceramics having a more complex structure, such as radiation emitting phosphors (for example, YAG:Ce (y₃Al₅O₁₂:Ce) and various halophosphate, phosphate, silicate, aluminate, borate and tungstate phosphors) and scintillators (for example, LSO, BGO, YSO, etc.). If desired, other materials, such as ZnO, quartz or glass may also be used. While oxide materials (such as metal or semiconductor oxides) are preferred, nitride materials, such as aluminum or silicon nitride, may also be used. Other powders may also be used, such as metal and semiconductor powders.

The powder may be prepared by any suitable powder formation method, such as milling or grinding. Commercially available ceramic powder may be used, for example.

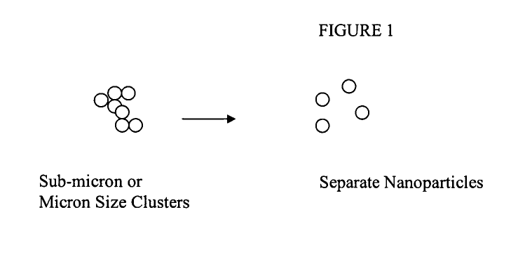

The powder may be mixed with a solid phase and/or with a liquid phase etching material which etches the powder particles to nanoparticles with a desired size distribution. Preferably, this etching material uniformly etches the powder to break up clusters of nanoparticles at an elevated temperature. Preferably, a by-product of the powder and/or the etching material generated during the elevated temperature etching process passivates or in-situ modifies the nanoparticle surfaces which hinders reformation of submicron nanoparticle clusters (i.e., keeps the nanoparticles separated). The passivation may comprise an elemental passivation of the nanoparticle dangling bonds and/or a thin layer of passivation molecules. A schematic diagram of the powder containing the nanoparticles clusters and the separated nanoparticles is shown in FIG. 1.

In a first embodiment of the invention, the etching material is provided in the solid state. The etching material may be mixed with the powder. The mixture is then heated to a temperature at which the etching material is dissolved into the liquid state while the powder material remains in the solid state. The liquid etching material then etches the powder and dissolves the nanoparticle clusters, such as submicron hard clusters, to provide the desired nanoparticle size distribution.

In a second embodiment of the invention, the etching material is provided in the liquid state. The powder is provided into the liquid etching material or into a solution into which the liquid etching material is provided before and/or after the powder. The liquid containing the etching material and the powder is heated to a temperature below which the powder is converted to the liquid phase. The liquid etching material then etches the powder and dissolves the nanoparticle clusters to provide the desired nanoparticle size distribution.

Preferably, in the processes of the first and the second embodiments, the heating facilitates a chemical reaction between the etching material and the powder. Preferably, the heating causes a chemical reaction between the metal or semiconductor element (such as elements from Groups IA-IVA and IB-VIIIB of the Periodic Table of Elements) of the powder compound and a portion of the etching material compound, such as a Group VIIA element (such as Cl, F or Br) or acetate or nitrate groups of the etching material. For example, the reaction between aluminum oxide powder and hydrochloric acid etching material results in generation of aluminum chloride. Likewise, for a semiconductor oxide or nitride powder, such as silicon oxide or nitride, and a hydrochloric or hydrofluoric acid etching material, a silicon-chlorine or silicon-fluorine compound is generated. For an acetic or nitric acid etching materials, a metal or semiconductor acetate or nitrate results from the reaction. The chemical reaction assists in generating nanoparticles with the desired size. Furthermore, the heating may be used to drive off water and other impurities which are undesirable in the nanoparticles.

Using the process of the first or second embodiments, the particle sizes can be tuned continuously from less than 5 nm to 100 nm. Due to the simplicity, uniformity and rapidness of this process, nanoparticles of any material can be fabricated in large quantities with very narrow size distribution compared to prior art methods, such as ball milling and pyrolysis. Examples of nanoparticles include: Al₂O₃, CeO₂, ZrO₂, ZnO, SiO₂, TiO₂, etc.

The method of the first embodiment in which the etching material is initially provided in the solid phase will now be described. The inventors believe that sub-micron particles may not be single particles but hard clusters of nanoparticles (primary particles). During the synthesis of the sub-micron particles or powders at high temperature, the nanoparticles coalesce together into a hard cluster that is difficult to break. The first embodiment provides a “two-phase” etching and nucleation process to reliably etch sub-micron clusters and preserve nanoparticles in solid form. The process is explained by referring to a sample method involving alumina powder and aluminum chloride etching material. However, any other suitable powder, such as a metal or semiconductor oxide powder, and any other suitable etching material, such as a metal or semiconductor chloride, fluoride or bromide material may be used. Preferably, the powder and the etching material contain the same metal or semiconductor component (i.e., aluminum oxide and chloride, zinc oxide and chloride, etc.). The etching material has a lower melting point than the powder.

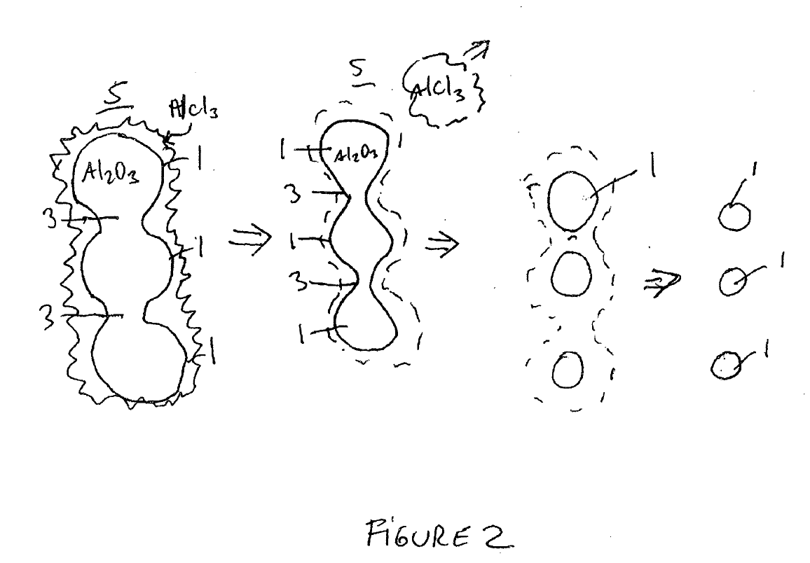

If two solids such as Al₂O₃ and AlCl₃ are mixed together (both being present as sub-micron powders) and then heated, the AlCl₃ melts first and coats the Al₂O₃. The chlorine present in the AlCl₃ promotes localized etching of the clusters. Since the chlorine etches Al₂O₃ everywhere uniformly, the regions in the cluster where particles had originally joined etches off faster separating the particles, as shown in FIG. 2. In other words, as shown in FIG. 2, since the regions 3 joining the alumina nanoparticles 1 in the cluster 5 are thinner than the nanoparticles 1 themselves, and since the chlorine (from aluminum chloride) etches alumina at a uniform rate, the etching material will etch away the joining regions 3 before it dissolves the nanoparticles 1. Thus, the joining regions 3 are dissolved while the nanoparticles 1 in the cluster 5 are merely reduced to a desired size.

The primary nanoparticles 1 and their shape may also change slightly due to this process. However, the particles maintain their original crystallographic structure and phase. During the cooling process, the dissolved Al₂O₃ in AlCl₃ may also precipitate as new nanoparticles particles or epitaxially grow on the primary particles. The phase of the new particles can be different than the original ones and this helps in keeping the particles separate or even if they re-join, the physical layer between the particles being thinner and easier to break in subsequent processing, such as sonication.

An example of a method of generating nanoparticles according to the first embodiment is provided below.

In a first pre-mix step, metal oxide powder and solid metal chloride etching material are measured out in molar equivalents. A higher concentration of metal chloride may reduce particle size. For example, for each 1 kg of alumina, 1.3 kg of aluminum chloride may be used. The weight ratios may range from 1:0.5 to 1:10, such as 1:1.1 to 1:2 or 1:1.1 to 1:3. The oxide powder may have an average diameter of 100 nm or greater, such as 100 nm to 100 microns, for example.

In a second mixing step, the powders are added to equipment that will homogeneously mix and reduce particle sizes. Any suitable mixing equipment may be used, such as a ball mill, tumbler, grinder, high shear mixer, etc. or manual mixing implements, such as mortar and pestle. Material is mixed for a period of time depending on equipment used, such as up to 3 hours for ball milling. It is desirable to coat oxide particles with chloride particles and to make the particles as small as possible during the mixing step.

In a third heat treatment step, the mixed powders are placed into a furnace or other heating device where the temperature controls are set to between about 500° C. and about 700° C. For example, 600° C. may be used in a box furnace. Other temperatures above 700° C. or below 500° C. may also be used depending on the material being etched and other process conditions. Thus, the heat treatment step is preferably carried out at a temperature of at least 500° C. The powder mixture is heat treated for about 2 to about 4 hours at the desired temperature. As discussed above, the aluminum chloride melts and coats the alumina particles. The aluminum chloride etches the alumina particles and hard clusters to obtain alumina nanoparticles with the desired size and aluminum and/or chlorine containing passivation. The chlorine from aluminum chloride is removed in gaseous form while some remains in the material as HCl and trapped Cl₂ gas.

In a fourth cleaning or cleansing step, powder form material is removed and rinsed. The rising material varies based on the powder material, and includes deionized water, tap water and additives of HCl, NH₄OH, acetic acid and other pH modification chemicals. Any suitable rinsing equipment may be used, such as a planetary mixer where the powder is added to a prepared liquid suspension already being agitated. However, other equipment may be used. The rising time varies between 10 and 30 minutes. For example, approximately 15 minutes may be sufficient, but longer provides better removal of chlorides. The mixture is then allowed to sit or settle for a period of time ranging from 15 minutes to several hours to allow metal oxides to separate from the cleaning solution. The cleaning solution is then removed. If needed, additional cleaning steps can be used to further reduce the amount of chlorides in the material. Different rinses can be used to provide higher quality powders versus suspensions.

In a fifth powderization step, the wet powder is dried. The wet powder is placed into an oven or furnace and raised to a temperature 100° C. or greater, such as 300F (150° C.) or greater to remove all water in the suspension. A temperature of 400 F may be used and a convection oven provides efficient water removal processing. Other heat treatment equipment, such as a hot plate, and temperatures can be selected to optimize the process to meet different requirements.

In an optional sixth suspension step, if it is desired to store the nanoparticles in a suspension, then a suspension mixture (e.g., colloid) is prepared. The nanoparticles are provided into a liquid, such as for example by slowing adding the nanoparticles into a liquid located in a planetary mixer. For example, the nanoparticles may be added a rate of 10 to 500 g/min, such as 100 g/minute. The suspension mixing can be done for 2 to 8 hours depending on amount of material, concentration, target pH, etc. Some soft clustered particles break into smaller clusters or primary particles during this process and some remain larger. This suspension mixture is finally run through a sonication system where it breaks remaining soft clusters. Typical concentrations at this stage range between 2% and 10% loading of metal oxide to liquid.

In a second embodiment of the invention, the metal or semiconductor oxide powder is combined with a liquid etching material. The etching liquid may be provided into a solvent before or after the powder is provided into the solvent. If desired, the etching liquid itself may be used as a solvent. Alternatively, the etching liquid itself may comprise a first solution which is added to a second solution before or after the powder is added to the second solution. For example, water may be used as a solvent and hydrochloric, acetic or nitric acid may be used as an etching material. The temperature of the solution is then raised to facilitate the reaction of the etching material and the powder. For example, the temperature may be raised above 200° C., such as above 500° C., for example between about 500 and about 700° C. Examples of materials include aluminum oxide and hydrochloric acid which may react to form aluminum chloride. Zinc oxide and acetic or nitric acid may react to form zinc acetate or zinc nitrate. The reaction facilitates the nanoparticle formation. The solution is then cooled. Specific parameters for liquid phase etching methods to form nanoparticles are described in PCT Published Application WO 2005/013337 filed on Mar. 3, 2004 and in its U.S. counterpart application serial number 10/547,795, both of which are incorporated herein by reference in their entirety. These or similar parameters may be used for elevated temperature etching according to the method of the second embodiment.

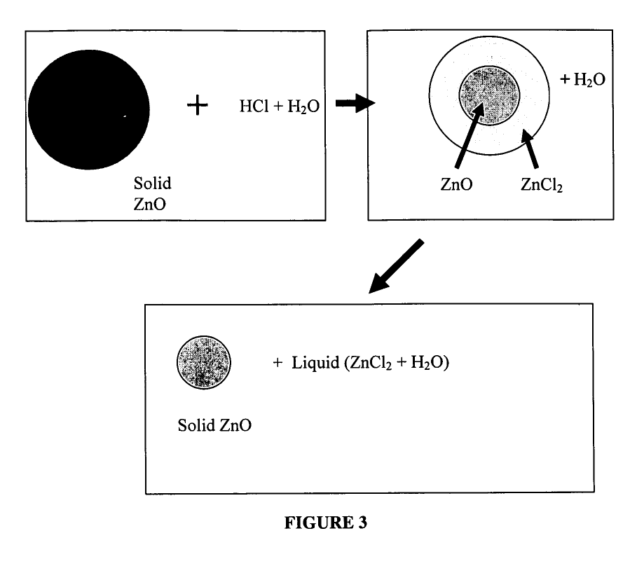

Thus, nanoparticles or nanocrystals having sizes in the range of 2-100 nm and with size distribution in the range of 10-25% of the average size can be made using the method of the first or second preferred embodiment. The etching liquid reduces the size of the nanoparticles to the desired size by etching the nanoparticles (see FIG. 3). Thus, the etching “tunes” the nanoparticles to a desired size. The general (unbalanced) reaction chemistries for the etching step of alumina and ZnO nanoparticles are shown below:
Al₂O₃+H₂O+HCl→AlCl₃+Al₂O₃+H₂O (1)
ZnO+H₂O+HCl→ZnO+ZnCl₂+H₂O (2)

The excess passivating element in the solution, such as aluminum or zinc or chlorine, then repassivates the surface of the etched nanoparticles. By selecting an appropriate type and amount of etching medium, the large nanoparticles can be automatically etched down to a uniform smaller size. If the acid concentration is the solution exceeds the desired amount then the nanoparticles are completely dissolved.

To narrow the size distribution, one or more purification or particle separation steps are may be performed. One such particle separation step comprises centrifuging a container containing the solution after the etching step (i.e., centrifuging the solution containing the formed nanoparticles). Distilled water is added to the sample and the nanoparticles are agitated back into solution in an ultrasonic vibrator. The process of centrifuging and washing may be repeated a plurality of times, if desired.

The above solution is then filtered through mesh or filters after the steps of centrifuging and washing. The mesh or filter can be from made from randomly oriented stacks of cellulose, spherical columns of dielectric materials, polymers, nano-porous media (such as alumina or graphite).

An alternative method to make nanoparticles with a specific size is to decant the solution by storing it for several hours. A first set of heavy or large nanoparticles or nanoclusters settle at the bottom of the container. The second set of smaller nanoparticles still located in a top portion of the solution is separated from the first set of nanoparticles and is removed to a new container from the top of the solution. This process can be repeated several times to separate nanoparticles with different size. During each successive step, the original reagent solution is diluted with a liquid medium which does not dissolve the nanoparticles, such a water. The decanting step may be used instead of or in addition to the centrifuging and filtering steps.

After fabrication, storage and/or transportation, the nanoparticles may be suspended in fluid, such as a solution, suspension or mixture. Suitable solutions can be water as well as organic solvents such as acetone, methanol, toluene, alcohol and polymers such as polyvinyl alcohol. Alternatively, the nanoparticles are located or deposited on a solid substrate or in a solid matrix. Suitable solid matrices can be glass, ceramic, cloth, leather, plastic, rubber, semiconductor or metal. The fluid or solid comprises an article of manufacture which is suitable for a certain use.

The nanoparticles made by the method of the first or second preferred embodiment comprise nanoparticles having an average size between about 2 nm and about 100 nm with a size standard deviation of less than 60 percent of the average nanoparticle size determined by photon correlated spectroscopy (PCS) method. The PCS method is used to determine the size of nanoparticles in a suspension. The size of the nanoparticles can also determined using Secondary electron Microscopy (SEM), Transmission Electron Microscopy (TEM) or Atomic Force Microscopy (AFM). Preferably, the nanoparticles have an average size between about 2 nm and about 10 nm with a size standard deviation of between about 10 and about 25 percent of the average nanoparticle size determined by photon correlated spectroscopy (PCS) method.

The nanoparticles may be used in various fields of technology, such as nanotechnology, semiconductors, electronics, biotechnology, coating, agricultural and optoelectronics, such as in abrasives (including chemical mechanical polishing powder), thermal and conductivity altering additives, UV absorbing materials, opacity additives and catalysts. The nanoparticles may comprise, for example, alumina, ceria, zirconia, zinc oxide, silica and titania.

In a third embodiment of the invention, the by-products of the etching and chemical reaction are recycled to form additional nanoparticles to increase the yield of the nanoparticle formation process. For example, the following reaction produces a metal chloride by-product: ZnO (powder)+HCl+H₂O=ZnO (nanoparticles of smaller size than the powder)+ZnCl₂+H₂O.

The following three exemplary processes will be described with respect to zinc oxide. However, other nanoparticles, such as alumina, ceria, zirconia, zinc oxide, silica and titania (i.e., having a formula AB, where A comprises at least one element from Groups IA-IVA and IB-VIIIB, and B comprises at least one element from group VIIA) may be formed using this process. In these cases, the metal or semiconductor chloride or other by-product is recycled. It should be noted that the recycling method of the third embodiment may be used with elevated temperature etching methods of the first or the second embodiments or with room temperature etching described in the PCT Published Application WO 2005/013337 filed on Mar. 3, 2004 and in its U.S. counterpart application serial number 10/547,795.

In a first exemplary process, after etching, the ZnCl₂ is eventually recycled to form ZnO by adding an oxidizing material, such as a hydroxide, including NaOH, NH₄OH or KOH:
ZnCl₂+NaOH+H₂O=Zn(OH)₂+NaCl+H₂O

This forms the metal or semiconductor hydroxide. The pH is then changed to coagulate the ZnO (i.e., to compress volume). Then, the water with chlorides is removed. Optionally, ZnO can be transferred into toluene or other organic solvent which will leave chlorides suspended in water for removal. Solvent can then be driven off or material resuspened in clean water for removal. Then, a surfactant may be added to preserve particle separation. The powder is heated to drive off H₂O and then heated to 300° C. or more to convert the metal or semiconductor hydroxide to an oxide (i.e., Zn(OH)₂ to ZnO). The powder may be suspended in water or other solvents with surfactant.

In a second exemplary process, after etching, the ZnCl₂ is recycled to form Zn(OH)₂ by adding NaOH or NH₄OH, KOH or any other hydroxide. A surfactant and toluene are added to separate the zinc compound and hydroxides from water. The water with chlorides is removed. The resulting powder is washed repeatedly in water and then heated to drive off H₂O. It is then heated to 300° C. or more to convert Zn(OH)₂ to ZnO. The powder may then be suspended in water or other solvents with surfactant.

In a third exemplary process, the metal or semiconductor chloride is recycled in an oxygen ambient at a high temperature to form a metal or semiconductor oxide directly. For example, after etching, the ZnCl₂ is recycled in an oxygen ambient to form ZnO directly by heating to 400-600° C.:
ZnCl₂+O₂=ZnO+Cl₂

The powder may then be suspended in water or other solvents with surfactant. Thus, the process yield is improved due to the recycling step and the impurities in the nanoparticles are reduced due to evaporation of Cl₂.

The following examples are provided for illustration of an embodiment of the invention and should not be considered limiting on the scope of the claims.

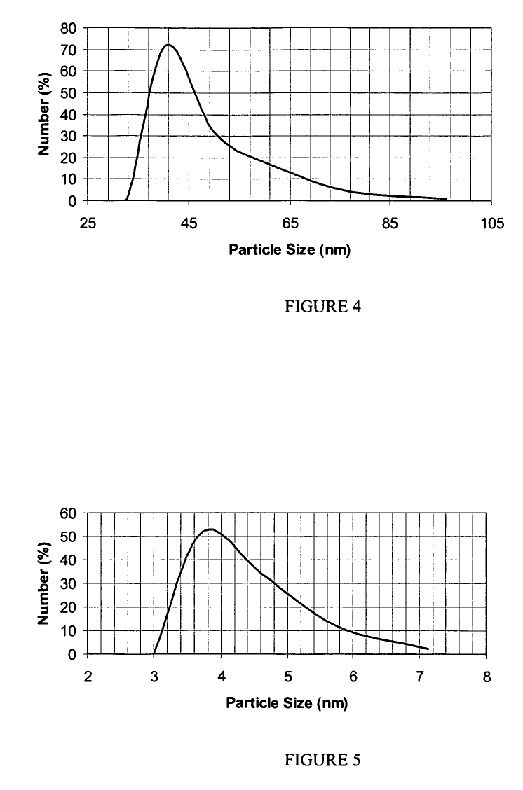

In the first example, 50 grams of a commercial grade 0.1 micron size Al₂O₃ powder (from South Bay Technology) is mixed with 50 grams of dried aluminum chloride powder. The two powders are mixed thoroughly for 2-3 hours using a mortar and pestle. The mixed powder is then heated to 685° C. for 2 hours and then cooled down to room temperature within 60 minutes. The resulting dry powder is then suspended in water and centrifuged to extract the undissolved powder (alumina). The powder is washed 4-5 times with water to extract (by dissolving) the unreacted aluminum chloride. The centrifuged powder is dried by evaporating the water around 100° C. on a hot plate. The powder is then weighed. The powder is then suspended in water at room temperature and the particle size distribution measured by PCS. FIG. 4 shows the particle size distribution in a sample in which the weighed powder was determined to weigh 48 grams. The average particle size is around 40 nm, which is significantly less than the 100 nm average particle size of the starting alumina powder.

In a second example, 25 grams of the starting 0.1 micron alumina powder is mixed with 75 grams of dried aluminum chloride powder. The two powders are mixed thoroughly for 2-3 hours using a mortar and pestle. The mixed powder is then heated to 685° C. for 2 hours and then cooled down to room temperature within 60 minutes. The resulting dry powder is then suspended in water and centrifuged to extract the un-dissolved powder (alumina). The powder is washed 4-5 times with water to extract (by dissolving) the unreacted aluminum chloride. The centrifuged powder is dried by evaporating the water around 100° C. on a hot plate. The powder is then weighed. The powder is then suspended in water at room temperature and the particle size distribution measured by PCS. FIG. 5 shows the particle size distribution in a sample in which the weighed powder was determined to weigh approximately 19 grams. The average particle size is about 4 nm which is significantly less than the 100 nm average particle size of the starting alumina powder.

It is concluded from these experiments that the ratio of Al₂O₃ (metal oxides) to AlCl₃ (metal chlorides) results in different particle sizes in the final metal oxide samples. Similar results are expected in other oxide materials such as ZnO, CeO₂, ZrO₂, etc.

The foregoing description of the invention has been presented for purposes of illustration and description. It is not intended to be exhaustive or to limit the invention to the precise form disclosed, and modifications and variations are possible in light of the above teachings or may be acquired from practice of the invention. The drawings and description were chosen in order to explain the principles of the invention and its practical application. It is intended that the scope of the invention be defined by the claims appended hereto, and their equivalents.

U.S. Pat. No. 6,906,339, U.S. provisional application serial number 60/452,041 and PCT published application WO 2005/013337 are incorporated herein in their entirety by reference.

What is claimed is:

1. A method of making nanoparticles, comprising:
contacting a powder having particles of a first size and an etching material; and
heating the powder and the etching material to reduce particles of the first size to nanoparticles having a second size smaller than the first size.

2. The method of claim 1, wherein the powder is selected from the group consisting of silica, alumina, titania, zinc oxide, zirconia, yttria stabilized zirconia, yttria, ceria, spinel and tantalum pentoxide.

3. The method of claim 1, wherein the etching material comprises a solid etching material.

4. The method of claim 3, wherein:
the etching material comprises a metal or semiconductor chloride; and
the heating step is conducted at a temperature at which the etching material melts but the powder does not melt.

5. The method of claim 4, wherein the etching material comprises aluminum chloride and the powder comprises alumina.

6. The method of claim 3, wherein the step of contacting the powder having particles of the first size and the etching material comprises mixing the powder and an etching material powder.

7. The method of claim 1, wherein the etching material comprises a liquid etching material.

8. The method of claim 7, wherein the etching material comprises an acid.

9. The method of claim 1, wherein the etching material uniformly etches the powder to dissolve clusters while reducing particle size.

10. The method of claim 1, wherein the powder comprises a metal oxide or a semiconductor oxide powder.

11. The method of claim 10, wherein a chemical reaction between the powder and etching material forms a by-product compound.

12. The method of claim 11, further comprising oxidizing the by-product to generate additional metal or semiconductor oxide nanoparticles.

13. The method of claim 1, wherein the step of heating comprises heating the powder and the etching material to at least 500° C.

14. The method of claim 1, wherein the nanoparticles have an average size of 2 to 50 nm.

15. The method of claim 14, wherein the powder having particles of a first size comprises a powder having an average diameter of 100 nm or greater.

16. A method of making nanoparticles, comprising:
etching a metal oxide powder with an etching material to generate metal or semiconductor oxide nanoparticles and a by-product; and
oxidizing the by-product to generate additional metal or semiconductor oxide nanoparticles.

17. The method of claim 16, wherein the etching material comprises a chloride material and the by-product comprises a metal chloride or a semiconductor chloride.

18. The method of claim 17, wherein the step of oxidizing comprises:
combining the chloride by-product with a hydroxide in a solution to convert the chloride by-product to a hydroxide by-product; and
converting the hydroxide by-product to the metal oxide or the semiconductor oxide nanoparticles.

19. The method of claim 17, wherein the step of oxidizing comprises exposing the by-product to an oxygen containing ambient at an elevated temperature to convert the chloride by-product to the metal oxide or the semiconductor oxide nanoparticles.
